(19) United States
(12) Patent Application Publication
(10) Pub. No.: US 2018/0313908 A1
(43) Pub. Date: Nov. 1, 2018

(54) SYSTEM FOR CONTINUOUSLY CALIBRATING A MAGNETIC IMAGING ARRAY

(71) Applicant: QuSpin, Inc., Louiville, CO (US)

(72) Inventors: Svenja Knappe, Boulder, CO (US); Orang Alem, Lafayette, CO (US); Vishal Shah, Westminister, CO (US)

(73) Assignee: QuSpin Inc., Louisville, CO (US)

(21) Appl. No.: 15/581,008

(22) Filed: Apr. 28, 2017

(51) Int. Cl. G01R 33/00; G01R 33/032

(52) U.S. Cl. CPC G01R 33/0035; G01R 33/032

(57) ABSTRACT

A calibration system and method is described to continuously measure and adjust several parameters of a magnetic imaging array. One or more non-target magnetic field source(s) are used to generate a well-defined and distinguishable spatial magnetic field distribution. The magnetic imaging array is used to measure the strength of the non-target magnetic fields and the information is used to calibrate several parameters of the array, such as, but not limited to, effective magnetometer positions and orientations, gains and their frequency dependence, bandwidth, and linearity. The calibration can happen continuously or periodically, while the imaging array is operating to create magnetic field images, if the modulation frequencies for calibration are outside the frequency window of interest.

The following application is an application for patent under 35 USC 111 (a). This invention was made with government support under HD074495 awarded by the National Institutes of Health. The government has certain rights in the invention.

### FIELD OF INVENTION

This disclosure relates to the field of calibrating a magnetic imaging array, specifics y a system and method thereof.

### BACKGROUND

Optically pumped magnetometers (OPMs), also called atomic magnetometers, optical magnetometers, or optical atomic magnetometers, are used in a number of scientific and advanced technology applications including medical imaging. In their simplest form, these sensors contain a light source, a container to hold atoms, and a detector. The light source may be a laser or other optical device used to produce light of a certain wavelength. The container may be a vapor cell or other device used to house atoms. The detector would necessarily be specific to the light output.

Single OPMs or small arrays of OPMs have been used routinely to create magnetic field images or gradient magnetic field images and to localize magnetic sources. In many cases, the sensors or sensor arrays are mounted onto moving platforms and moved in regular patterns over the area of interest. Alternatively, larger arrays allow the sensors to be stationary. In order to localize magnetic sources, the positions of the sensors have to be known. For large area images, the sensor location can be determined with global navigation satellite systems (GNSS), such as but not limited to the global positioning system (GPS). For smaller areas of interest, sensor positions have been determined geometrically or optically. For some OPMs, an additional complication comes from the fact that the position at which the magnetic field is measured, is determined by the position of the light or laser beam, not a physical component of the sensor.

There are several other factors that determine the quality of the image and the source localization apart from the locations of the sensors in the array, such as but not limited to, sensor orientation, sensor gain as a function of frequency, sensor bandwidth, sensor cross-talk, and sensor linearity. All these sensor array parameters are usually calibrated at least once before the measurement.

### SUMMARY OF THE INVENTION

Optically-pumped magnetometers can be arranged into flexible arrays, which results in the need to determine all sensor positions and orientations every time the array configuration is changed. In addition, the orientation of the sensing axes of each magnetometer in the array is affected by cross-talk from neighboring sensors. Furthermore, parameters such as the gain, the bandwidth, and the linearity could vary with changes in the light power or background magnetic fields. Due to limited bandwidths of optically-pumped magnetometers, the gain also has a frequency dependence within the frequency range of interest, which can change as laser or vapor cell parameters change. These parameters therefore require frequent calibration, in order to create high-resolution images.

In prior art, Kim et al. (K. Kim et al, NeuroImage 89, 143 (2014)) have calibrated the position and orientation of an OPM-based sensor array by applying a set of calibrated linear magnetic field gradients to the array prior to use. The magnetometers were then utilized to determine the magnetic field at the location of the atoms. This allowed deduction of the exact “effective” sensor positions and orientations at the time of calibration but not throughout the duration of the measurement of the target fields or data collection.

Magnetoencephalography (MEG) uses large imaging arrays, of often hundreds of magnetometers, to measure magnetic fields produced by head and brain tissue. These magnetometers were traditionally superconducting quantum interference devices, but recently OPMs have also been employed. Several methods to calibrate the magnetometer positions in the imaging array have been developed. Most of them use a set of dipolar sources in the form of coils whose relative positions and orientations are precisely known prior to data collection. The magnetic field distributions are measured with the magnetometer array and the values are compared to theoretical models. This allowed estimation of the magnetometer positions and orientation with respect to each other and the source array (A. Bruno and P. Costa Ribeiro, Rev. Sci. Instrum., Vol. 62, 1005, 1991; R. Kraus Jr. et al., Biomedizinische Technik 46, 38, 2001; A. Pasquarelli et al., Neurology and Clinical Neurophysiology, 94, 1, 2004; Y. Adachi et al., IEEE Trans. Mag. 50, 5001304, 2014; V. Vivaldi, Biomag 2014, Aug. 24-28, Halifax, Canada). Further, Chella et al. (Chella et al., Phys. Med. Biol. 57, 4855, 2012) used a method to compensate for external interference and sensor artifacts to determine the magnetometer positions.

In several previous MEG applications, OPM positions and orientations have been determined geometrically before or after the measurement. In Boto et al. (E. Boto et al., PLOS ONE 11, e0157655, 2016), a snug-fitting printed headcast was used to tightly constrain the outer dimensions of the sensors and the effective sensor position was calculated from that. In O. Alem et al. (O. Alem et al., Optics Express, 25, 7849 (2017)), a printed helmet allowed for sensor movement in the radial direction only and the radial position was recorded after every measurement. The sensor positions were then inferred from the geometric geometry.

All of these methods calibrate the array anywhere from one to several times and do not accommodate variations of the parameters of the imaging array during the measurement of the target magnetic field and/or data collection. The system and method described herein is broadly applicable to imaging systems with one or more sensors, such as magnetometers, positioned in different locations. The system and method described herein may also be particularly useful in situations in which the exact magnetometer locations or other parameters of the imaging array vary over the course of the measurement. These parameters may include gain, bandwidth, orientation, cross-talk, or linearity.

Briefly describing the invention, the system and method includes at least one or multiples of non-target magnetic field producing sources, generating well-defined magnetic field distributions that vary over the spatial area covered by the at least one, but potentially hundreds of magnetometers of an imaging array. The positions and orientations of the non-target sources with respect to each other are known before data collection begins. One, or several parameters of the imaging array can be calibrated by simultaneously measuring the non-target and target magnetic fields. In other words, once data collection begins, signals are applied to the non-target sources in such a way that the magnetometers can identify the source it originates from. This is accomplished by, but may not be limited to, the signals from non-target sources being sinusoidal modulations at defined frequencies, where every source has its own frequency, or dipole frequencies or by temporally switching the sources on and off in a deterministic temporal pattern so that only one source operates at a time. The magnetometers are then measuring the strength of the signals of the non-target magnetic field as well as the target magnetic field. The strength of the non-target magnetic field is used to deduce the array parameter of interest and calibrate this parameter periodically.

In the invention, at least one non-target magnetic source, which produces a well-defined magnetic field pattern is operated. A magnetic imaging array, consisting of at least one magnetometer, is used to measure both the target and the non-target source. The information obtained from the measurements of the non-target magnetic sources is used to obtain information about the imaging array itself. This information is used to calibrate at least one parameter of the magnetic imaging array. Such parameters include, but are not limited to, magnetometer position, magnetometer orientation, magnetometer gain, linearity, and cross-talk between magnetometers.

The invention is a system for continuously calibrating a magnetic imaging array, the system comprising: at least one non-target magnetic source capable of creating a known magnetic field pattern; and an imaging array comprising at least one magnetometer, wherein the magnetometer is capable of simultaneously measuring the magnetic fields of the at least one non-target magnetic source and a target magnetic source; and a device that uses the magnetic field measurement from the at least one non-target magnetic source to generate at least one calibration parameter of the imaging array. A further embodiment is a method for continuously calibrating a magnetic imaging array, the method comprising the steps of: using at least one non-target magnetic source to create a known magnetic field pattern; measuring the known magnetic field pattern along with a target magnetic field to create a magnetic field measurement of the known field along with the target magnetic field measurement; and using the magnetic field measurement of the known field to produce a calibration parameter of the imaging array.

### BRIEF DESCRIPTION OF THE DRAWINGS

FIG. 1 is a schematic diagram illustrating the invention.

FIG. 2 is a schematic diagram illustrating several components of one embodiment of the invention.

FIG. 3 is a schematic diagram illustrating several components of a second embodiment of the invention.

FIG. 4 is an illustration of a third embodiment of the invention.

FIG. 5 is a schematic diagram illustrating an optically-pumped magnetometer imaging array and a set of dipolar sources as an embodiment of the system and method for continuously calibrating the positions, orientations and gains of the magnetometers of the imaging array.

FIG. 6 is a magnetic field spectrum of one of the magnetometers with responses from two non-target magnetic sources driven at two different frequencies and a target magnetic source measured simultaneously.

Before explaining the disclosed embodiments of the present invention in detail, it is to be understood that the invention is not limited in its application to the details of the particular arrangement shown, since the invention is capable of other embodiments. Also, the terminology used herein is for the purpose of description and not of limitation.

### DETAILED DESCRIPTION OF THE INVENTION

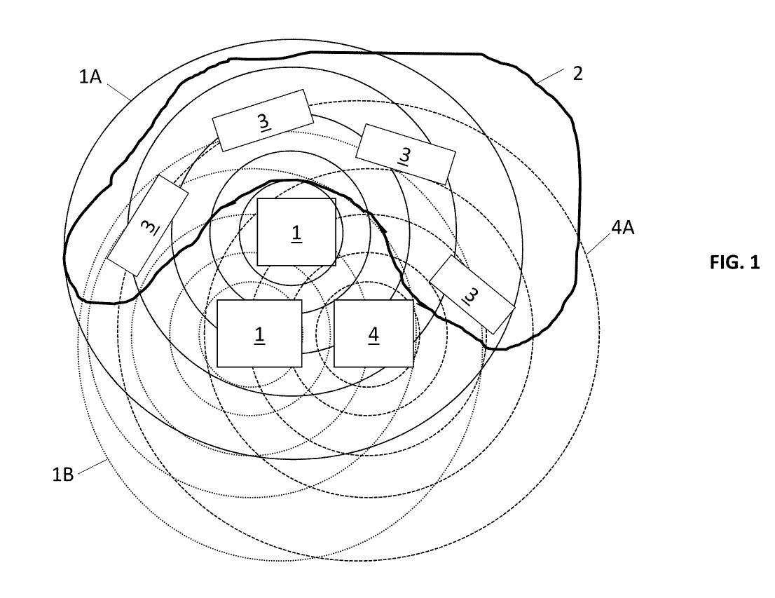

FIG. 1 is a schematic diagram illustrating the invention. One or more magnetic sources, being non-target magnetic sources, 1 are placed such that their positions and orientations with respect to each other are known. The non-target magnetic sources create non-target magnetic field patterns 1A and 1B, such that the magnetic field from each non-target magnetic source 1 is known over an area of interest 2. An imaging array, consisting of one or more magnetometers 3, are placed within the area of interest 2. The magnetometers 3 measure the magnetic field emitted by the non-target magnetic sources 1 as well as the target magnetic source(s) 4. The non-target magnetic fields patterns 1A, 1B are non-target magnetic fields created in such a way that they can be distinguished from the target magnetic fields 4A created by target magnetic source(s) 4. A non-target magnetic field or source is defined as a source, or magnetic field generated by a source, that is part of the input to a system, in other words in addition to any other background or target source of interest.

In order to distinguish between the non-target and target sources and not limit the measurements, the sources may generate fields within a narrow frequency band, where each non-target source could have its own frequency band outside the target measurement band of interest (frequency multiplexing). Alternatively, all sources could use the same frequency band and the sources are emitting successively, where only one non-target source is emitting at any given time (time multiplexing).

The non-target and target magnetic field information sensed by each of the magnetometers 3 is measured simultaneously and the target magnetic field information can be used to continuously or periodically calibrate parameters of the imaging array. These parameters include, but are not limited to magnetometer positions, orientations, cross-talk, gain, linearity, and bandwidth.

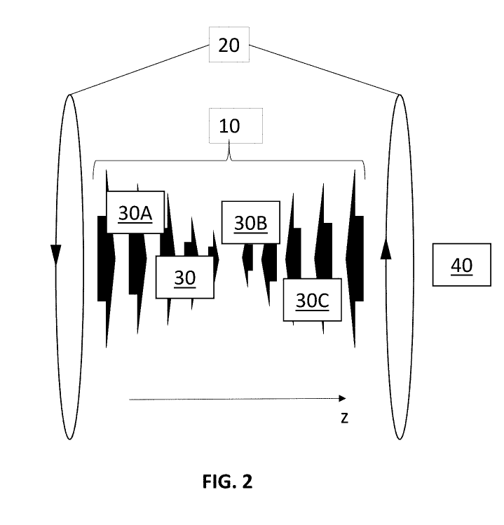

FIG. 2 represents a schematic diagram of one embodiment of the system and method for continuously calibrating a magnetic imaging array. In FIG. 2, a spatially varying magnetic field 10 is produced by a set of Maxwell coils 20, being the non-target magnetic field source, where the field strength varies linearly in the direction z. The current to the coils 20 is modulated at a certain frequency f. A magnetometer 30 placed anywhere between the two coils 20 measures a well-defined field amplitude at the frequency f. The magnetic field spectrum measured with the magnetometer will show a peak at frequency f, where the amplitude of the peak corresponds to the field strength at frequency f at the position z of the sensor. If the magnetometer is a directional sensor, the peak amplitude will also depend on the orientation of the sensor. Finally, the peak amplitude can also depend on additional parameters of the sensor, such as, but not limited to bandwidth, gain, and linearity. Several magnetometers can be placed in this gradient field to form an imaging array, as shown in FIGS. 2, 30A, 30B, and 30C. When field gradients in three orthogonal directions are applied, the positions of the sensors in the imaging array are measured simultaneously during the measurement of a magnetic field created by a target source of interest 40.

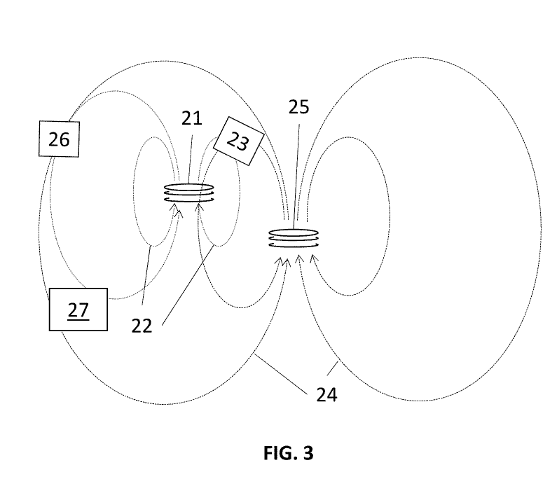

FIG. 3 is a schematic diagram illustrating a second embodiment of the invention. A first non-target source 21 continuously or periodically generates a magnetic field with a well-defined dipolar pattern 22. A first magnetometer 23 measures the value of the magnetic field at its location. The strength of the field measured with the first magnetometer 23 contains information about parameters of the first magnetometer 23. Such parameters could be, but are not limited to, the magnetometer position and orientation with respect to the source, the magnetometer gain, the magnetometer bandwidth, and/or the magnetometer linearity. A well-defined dipolar magnetic field pattern 24 from a second non-target source 25 is also measured with the first magnetometer 23. The strength of the field measured with the first magnetometer 23 also contains information about parameters of the first magnetometer. Additional non-target sources could be added to the source array. A second magnetometer 26 also measures the field from the first source 21, the second source 25, and any additional sources present. If the relative positions and orientations of the non-target sources are known, many parameters of the imaging array can be measured and calibrated simultaneously during measurement of target sources 27, thereby increasing accuracy of the target source measured.

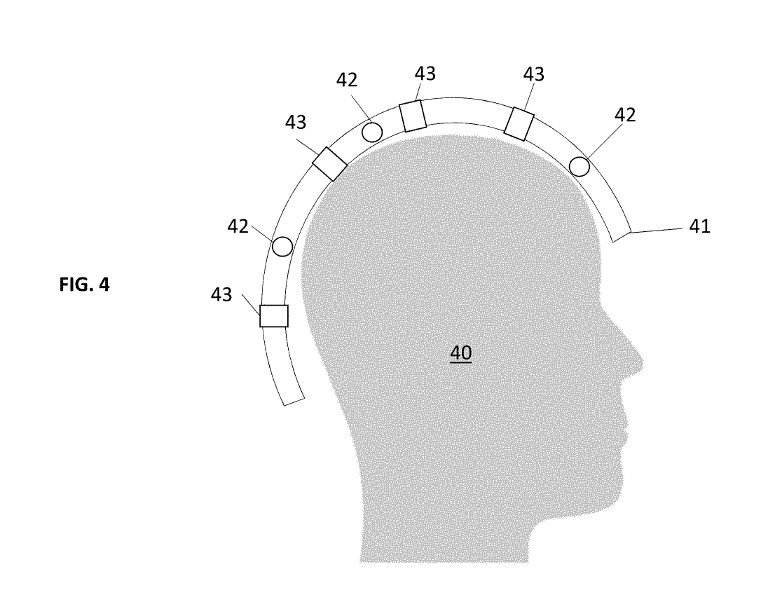

FIG. 4. is an illustration of a third embodiment of the invention. For magnetoencephalography, helmets or caps 41 with imaging arrays containing a number of magnetometers 43, are utilized to measure magnetic fields produced by brain tissue of a human subject 40. Non-target magnetic field sources 42 are placed in the cap 41 along with magnetometers 43. The magnetometers 43 simultaneously measure the target magnetic field emitted by tissue, cells, or other matter in the subject's brain 40 but also the non-target field produced by the one or more non-target magnetic field sources 42. This data is used to calibrate one or more parameters such as but are not limited to, the magnetometer position, orientation with respect to the source, the magnetometer gain, the magnetometer cross-talk, the magnetometer bandwidth, and/or the magnetometer linearity.

### EXAMPLES

### Example 1

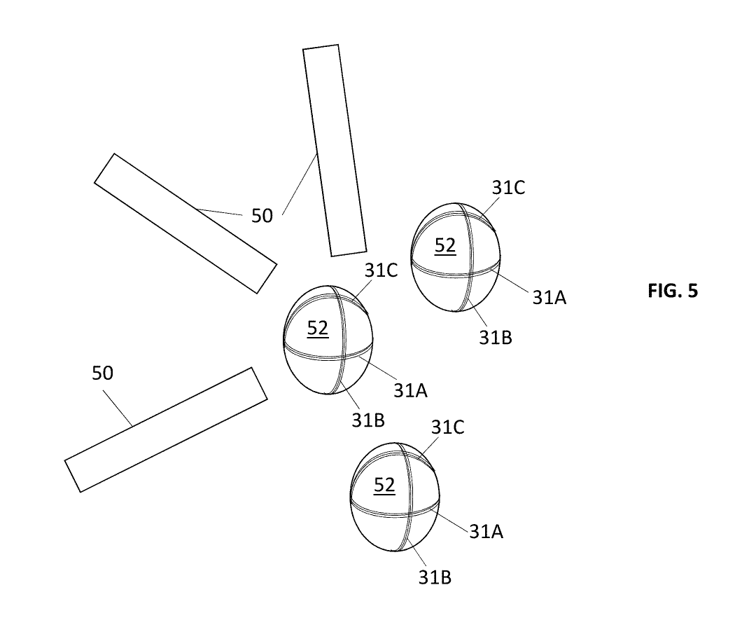

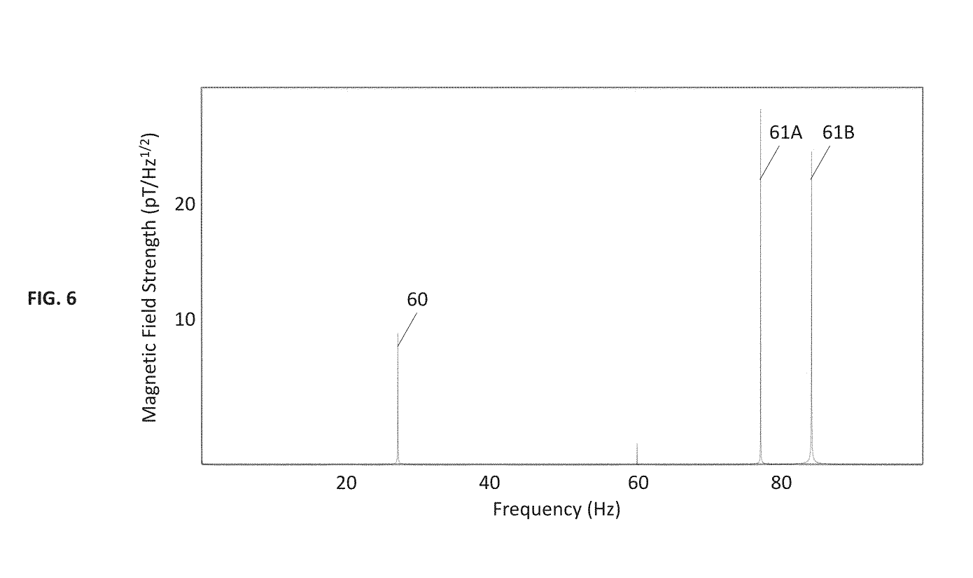

As an example, a simple magnetic imaging array has been constructed out of three optically-pumped magnetometers (OPMs) 50 as shown in FIG. 5. Each OPM 50 measured magnetic field(s) in two nearly orthogonal directions giving two channels of output data each. A schematic diagram of the imaging array is shown in FIG. 5. Three coils 31A, 31B, and 31C, were wrapped around each of three spheres 52 in nearly orthogonal directions serving as three dipolar sources. The spheres 52 were arranged and their relative positions and orientations measured carefully. The magnetic field of each of the dipolar sources was calculated relative to the sources themselves. Oscillating non-target magnetic fields were applied to the nine dipoles 31A, 31B, and 31C at modulation frequencies of 77 Hz, 78 Hz, 79 Hz, 80 Hz, 81 Hz, 82 Hz, 83 Hz, 84 Hz, and 85 Hz, respectively. The fields were recorded continuously in each of the six channels of the three OPMs 50. In order to record data with the OPM array simultaneously, the data stream was recorded with a data acquisition system. A low-pass filter was applied to remove the contributions of the calibration fields from the data of interest. In order to continuously calibrate the imaging array, the power spectral density of the time series was calculated before applying the low-pass filters. A measured magnetic field spectrum of one channel of one of the OPM sensors is shown in FIG. 6 with just two non-target sources active at 78 Hz and 82 Hz, 61A and 61B. At the same time a target magnetic source, i.e., the source of interest, created a target magnetic field with a peak at 27 Hz 60. The peaks at the modulation frequencies, 78 Hz and 82 Hz, 61A and 61B, can be seen clearly in FIG. 6 along with the target magnetic field at 27 Hz 60. The amplitudes of the peaks were used to calculate the effective position of the OPM sensors, the overall gain, as well as the effective directions of the two sensitive axes of each of the OPM sensors. The effective directions can vary when the DC background fields vary and due to cross-talk of the neighboring OPM sensors. All of the data was automatically included in the calibration deduced from the peak amplitudes of the modulation fields. Calibration values deduced from the modulation peaks were recorded along with the OPM data stream used to calibrate the array periodically, several times during the measurement.

### Example 2

The above example described how the present invention was used to continuously calibrate the positions, orientations and the overall gain of the imaging array. In the current example the bandwidth and related frequency dependence of the gain were continuously calibrated. Since in most OPMs, the bandwidth depends on laser parameters as well as DC background fields, it is prone to drift and requires frequent recalibration. In this example, a current dipole was continuously driven with the sum of several sinusoidal modulations at 100 Hz, 200 Hz, 300 Hz and 400 Hz of the same amplitude. The magnetic field was recorded continuously. With a bandwidth of the OPM around 150 Hz, the peaks in the power spectrum corresponding to these modulation fields were clearly seen to decrease with higher frequency. Notch filters were applied around the modulation peaks to the time series in order to minimize the effect of the modulation on the data. The amplitudes of the modulation fields at the different frequencies were then used to calculate correction factors that take the frequency-dependent gain and related bandwidth and phase shifts into account.

Although the present invention has been described with reference to the disclosed embodiments, numerous modifications and variations can be made and still the result will come within the scope of the invention. No limitation with respect to the specific embodiments disclosed herein is intended or should be inferred. Each apparatus embodiment described herein has numerous equivalents.

1. A system for continuously calibrating a magnetic imaging array, the system comprising:
a) more than one non-target magnetic source capable of creating a known magnetic field pattern with known amplitude at discrete frequencies not overlapping with other non-target or target magnetic source frequencies;
b) more than one magnetometer, wherein the magnetometers are capable of simultaneously measuring the magnetic fields of the non-target magnetic sources and the target magnetic source; and
c) a device that isolates the known magnetic field pattern produced by the non-target magnetic sources based on the frequency and uses a magnetic field measurement from the target magnetic sources to generate at least one calibration parameter of the magnetic imaging array based on a difference between an expected and a measured value of the isolated non-target magnetic fields.

2. The system of claim 1, wherein the magnetometers are optically-pumped magnetometers.

3. The system of claim 1, wherein the at least one non-target magnetic source is a dipolar source.

4. The system of claim 1, wherein the at least one calibration parameter of the magnetic imaging array is related to the position of the at least one magnetometer.

5. The system of claim 1, wherein the at least one calibration parameter of the magnetic imaging array is the orientation of the at least one magnetometer.

6. The system of claim 1, wherein the calibration parameter of the magnetic imaging array is the gain of the at least one magnetometer.

7. The system of claim 1, wherein the calibration parameter of the magnetic imaging array is the bandwidth of the at least one magnetometer.

8. The system of claim 1, wherein the calibration parameter of the magnetic imaging array is the linearity of the at least one magnetometer.

9. A method for continuously calibrating a magnetic imaging array, the method comprising the steps of:
a) using at least two non-target magnetic sources to create a known magnetic field pattern, wherein the at non-target magnetic sources produce a field pattern of known frequency and amplitude outside the range of a target magnetic field;
b) measuring, with at least two magnetometers, the known magnetic field pattern at the same time as the target magnetic field to create a magnetic field measurement of the known field along with a target magnetic field measurement; and
c) using the magnetic field measurement of the known field to produce a calibration parameter of the magnetic imaging array.

10. The method of claim 9, wherein step b is achieved with an optically-pumped magnetometer.

11. The method of claim 9, wherein the at least one non-target magnetic source is a dipolar source.

12. The method of claim 9, wherein the calibration parameter of the magnetic imaging array is the at least one magnetometer position.

13. The method of claim 9, wherein the calibration parameter of the magnetic imaging array is the at least one magnetometer orientation.

14. The method of claim 9, wherein the calibration parameter of the magnetic imaging array is the at least one magnetometer gain.

15. The method of claim 9, wherein the calibration parameter of the magnetic imaging array is the at least one magnetometer bandwidth.

16. The method of claim 9, wherein the calibration parameter of the magnetic imaging array is the at least one magnetometer linearity.

17. The system of claim 1, wherein the non-target magnetic sources produce sinusoidal modulations.

18. A system for continuously calibrating a magnetic imaging array, the system comprising:
a) at least two non-target magnetic sources capable of creating a magnetic field pattern of known amplitude and frequency, wherein the frequency lies outside the range of a target magnetic source, and wherein the magnetic field pattern is a sinusoidal modulation;
b) a plurality of magnetometers capable of simultaneously measuring the magnetic field pattern from the at least two non-target magnetic sources and the target magnetic source;
c) a device that isolates the magnetic field pattern from the non-target magnetic field sources and calculates a calibration parameter of the magnetic imaging array based on a difference between the expected amplitude and a measured amplitude.

19. A system for continuously calibrating a magnetic imaging array, the system comprising:
a) at least two non-target magnetic sources capable of creating a magnetic field pattern of known amplitude and frequency, wherein the frequency lies outside the range of a target magnetic source, wherein the magnetic field pattern is a dipole frequency;
b) a plurality of magnetometers capable of simultaneously measuring the magnetic field pattern from the at least one non-target magnetic source and the target magnetic source;
c) a device that isolates the magnetic field pattern from the non-target magnetic field source and calculates a calibration parameter of the magnetic imaging array based on a difference between the expected amplitude and a measured amplitude.
